(19) United States
(12) Patent Application Publication
(10) Pub. No.: US 2026/0173360 A1
(43) Pub. Date: Jun. 18, 2026

(54) SEMICONDUCTOR MEMORY DEVICE AND METHOD FOR FABRICATING THE SAME

(71) Applicant: Samsung Electronics Co., Ltd., Suwon-si, (KR)

(72) Inventors: Ho Jin KANG, Suwon-si (KR); Ji Ho PARK, Suwon-si (KR); Ga Eun LEE, Suwon-si (KR); Ji Won LEE, Suwon-si (KR); Kang Hyun SONG, Suwon-si (KR); Sang-Jun LEE, Suwon-si (KR)

(73) Assignee: Samsung Electronics Co., Ltd., Suwon-si, (KR)

(21) Appl. No.: 19/335,286

(22) Filed: Sep. 22, 2025

(30) Foreign Application Priority Data
Dec. 16, 2024 (KR) 10-2024-0186909

(51) Int. Cl. H10B 12/00

(52) U.S. Cl. CPC H10B 12/488; H10B 12/315; H10B 12/482

(57) ABSTRACT

There is provided a semiconductor memory device including an active pattern including a first side surface and a second side surface opposite to each other in a first direction, a conductive line extending on a bottom surface of the active pattern, a first insulating film extending on the first side surface of the active pattern in a second direction, a gate electrode extending on the second side surface of the active pattern in the second direction, and a data storage structure on an upper surface of the active pattern. The gate electrode includes a first gate portion and a second gate portion spaced apart from the active pattern, the second gate portion includes a convex surface that is convex toward the first insulating film, and a maximum length of the second gate portion is greater than or equal to a width of the active pattern in the first direction.

### CROSS-REFERENCE TO RELATED APPLICATION

This application claims priority from Korean Patent Application No. 10-2024-0186909 filed on Dec. 16, 2024 in the Korean Intellectual Property Office, and all the benefits accruing therefrom under 35 U.S.C. 119, the contents of which in its entirety are herein incorporated by reference.

### BACKGROUND

Example embodiments of the present disclosure relate to a semiconductor memory device and a method for fabricating the same. More specifically, example embodiments relate to a semiconductor memory device including a vertical channel transistor (VCT) and a method for fabricating the same.

Semiconductor devices with improved degrees of integration may be desired to satisfy higher performance and lower prices desired by consumers. In the case of semiconductor memory devices because the degree of integration may be an important factor in determining the price of a product, it may be advantageous to provide semiconductor memory devices including higher degrees of integration to meet the desired lower cost and higher performance.

In the case of two-dimensional or planar semiconductor memory devices, the degree of integration may be mainly determined by an area occupied by unit memory cells, and therefore may be greatly affected by the level of fine pattern forming technology. However, since the apparatuses primarily utilized to miniaturize the pattern may be cost limiting, the degree of integration of the two-dimensional semiconductor memory device may still be limited. Therefore, semiconductor memory devices including a vertical channel transistor and a channel extending in a vertical direction have been proposed.

### SUMMARY

Some example embodiments of the present disclosure provide a semiconductor memory device with improved performance and/or degree of integration.

Some example embodiments of the present disclosure also provided a method for fabricating a semiconductor memory device with improved performance and/or degree of integration.

However, some example embodiments of the present disclosure are not restricted to the one set forth herein. The above and other example embodiments of the present disclosure will become more apparent to one of ordinary skill in the art to which the present disclosure pertains by referencing the detailed description of some example embodiments of the present disclosure given below.

According to some example embodiments of the present disclosure, there is provided a semiconductor memory device comprising an active pattern including a first side surface and a second side surface opposite to each other in a first direction, a conductive line extending on a bottom surface of the active pattern in the first direction, a first insulating film extending on the first side surface of the active pattern in a second direction, the second direction intersecting the first direction, a gate electrode extending on the second side surface of the active pattern in the second direction, and a data storage structure on an upper surface of the active pattern. The gate electrode includes a first gate portion spaced apart from the active pattern in the first direction, and a second gate portion spaced apart from the active pattern in the second direction, the second gate portion includes a convex surface that is convex toward the first insulating film, and a maximum length of the second gate portion in the first direction is a distance from the second side surface of the active pattern to a furthest distance the second gate portion extends in the first direction, and the maximum length of the second gate portion is greater than or equal to a width of the active pattern in the first direction.

According to some example embodiments of the present disclosure, there is provided a semiconductor memory device comprising a first active pattern including a first side surface and a second side surface opposite to each other in a first direction, a second active pattern spaced apart from the first active pattern in a second direction, the second direction intersecting the first direction, a conductive line extending on a bottom surface of the first active pattern in the first direction, a first insulating film extending on the first side surface of the first active pattern in the second direction, a gate electrode extending on the second side surface in the second direction, a second insulating film between the first active pattern and the gate electrode, and between the second active pattern and the gate electrode, and a data storage structure on an upper surface of the first active pattern. The first insulating film includes a recess, recessed in the first direction, between the first active pattern and the second active pattern, and a part of the gate electrode extends toward the recess.

According to some example embodiments of the present disclosure, there is provided a semiconductor memory device comprising a first active pattern including a first side surface and a second side surface opposite to each other in a first direction, a second active pattern spaced apart from the first active pattern in a second direction, the second direction intersecting the first direction, a conductive line connected to the first active pattern and extending on a bottom surface of the first active pattern in the first direction, a first insulating film on the first side surface of the first active pattern extending in the second direction, a second insulating film extending along surfaces of the first active pattern, the second active pattern, and the first insulating film, a gate electrode on the second insulating film extending in the second direction, and a data storage structure connected to the first active pattern and on an upper surface of the first active pattern. The first insulating film includes a recess, recessed in the first direction, between the first active pattern and the second active pattern, the gate electrode includes a first gate portion on the first side surface of the first active pattern, and a second gate portion between the first active pattern and the second active pattern, and the second gate portion of the gate electrode includes a convex surface that is convex toward the recess.

According to some example embodiments of the present disclosure, there is provided a method of manufacturing a semiconductor memory device comprising forming an active film on a substrate, forming a first trench in the active film, forming a first insulating film in the first trench, forming a lower spacer, a back gate electrode, and a second upper spacer sequentially stacked in the first trench on the first insulating film, removing a portion of the active film to form a plurality of active patterns, recessing the first insulating film in a first direction, the first direction being parallel to an upper surface of the substrate, forming a second insulating film on the first insulating film and the plurality of active patterns, and the second insulating film extending in a second direction, the second direction being perpendicular to the first direction and parallel to the upper surface of the substrate, forming a gate electrode on the second insulating film extending in the second direction, forming a plurality of contact patterns on the plurality of active patterns in a third direction, the third direction being perpendicular to the upper surface of the substrate, and forming a data storage structure on the plurality of contact patterns in the third direction.

According to some example embodiments of the present disclosure, in the method of manufacturing a semiconductor memory device, in the forming the gate electrode, the gate electrode is formed to include a first gate portion, and a second gate portion extending between the plurality of active patterns in the first direction, and the second gate portion includes a convex surface that is convex toward the first insulating film.

It should be noted that the effects of the present disclosure are not limited to the example embodiments described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is an example layout diagram for explaining the semiconductor memory device according to some example embodiments.

FIG. 2 is a partially enlarged view for explaining a region R1 of FIG. 1.

FIG. 3 is a cross-sectional view taken along A-A of FIG. 1.

FIG. 4 is a cross-sectional view taken along B-B of FIG. 1.

FIGS. 5A to 5C are various partially enlarged views for explaining a region R1 of FIG. 1.

FIG. 6 is an example layout diagram for explaining a semiconductor memory device according to some example embodiments.

FIG. 7 is a partially enlarged view for explaining a region R2 of FIG. 6.

FIG. 8 is a cross-sectional view taken along C-C of FIG. 6.

FIGS. 9A to 9C are various other partially enlarged views for explaining a region R1 of FIG. 6.

FIGS. 10 to 30 are intermediate step diagrams for describing the method for fabricating the semiconductor memory device according to some example embodiments.

FIG. 31 is an intermediate step diagram for explaining a method for fabricating a semiconductor memory device according to some example embodiments.

FIG. 32 is an intermediate step diagram for explaining the method for fabricating the semiconductor memory device according to some example embodiments.

FIGS. 33 and 34 are intermediate step diagrams for describing the method for fabricating a semiconductor memory device according to some example embodiments.

### DETAILED DESCRIPTION OF THE EMBODIMENTS

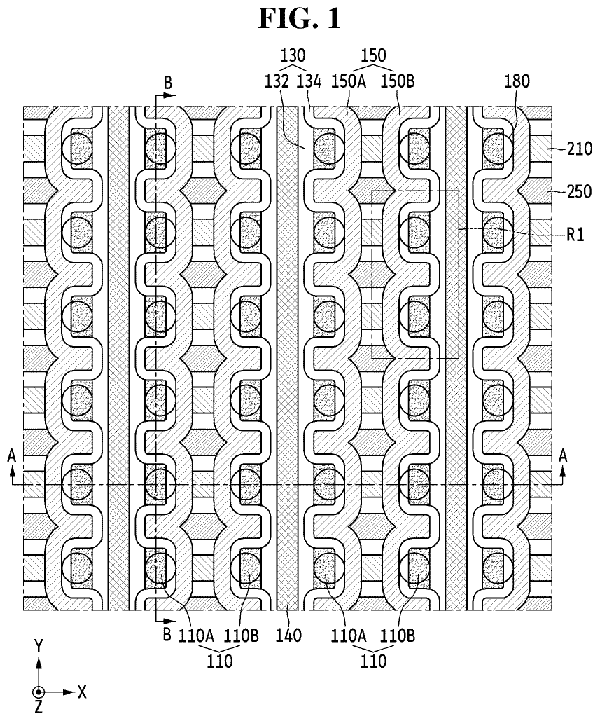

Hereinafter, a semiconductor memory device according to some example embodiments will be described referring to FIGS. 1 to 9C.

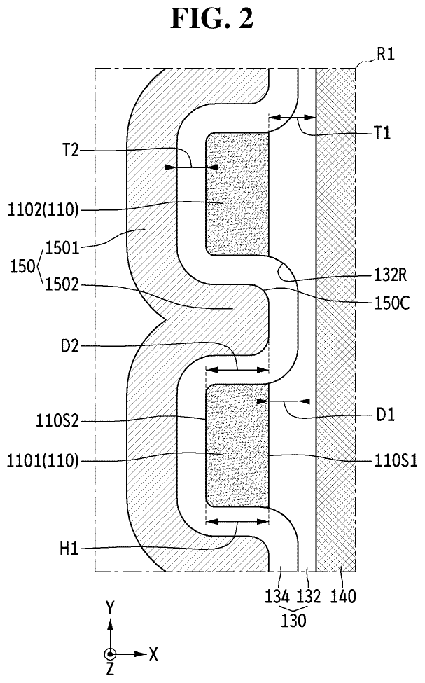

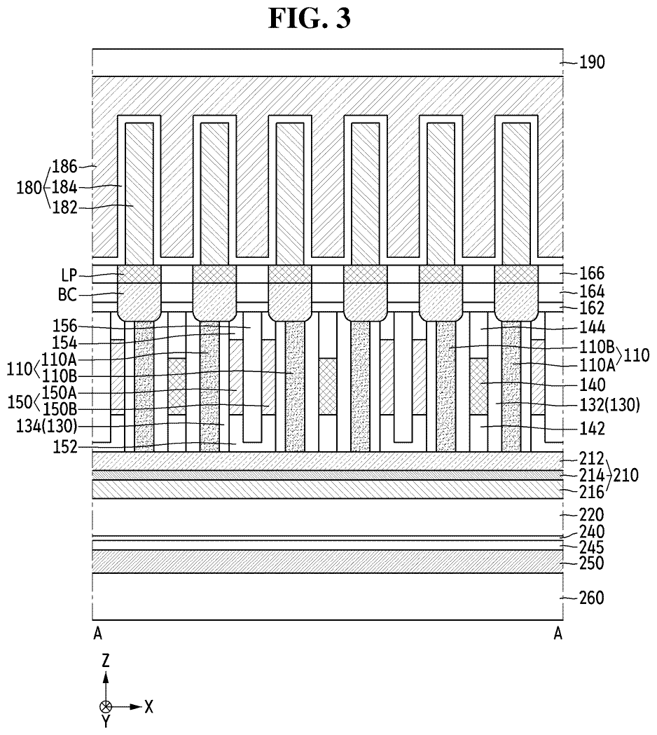

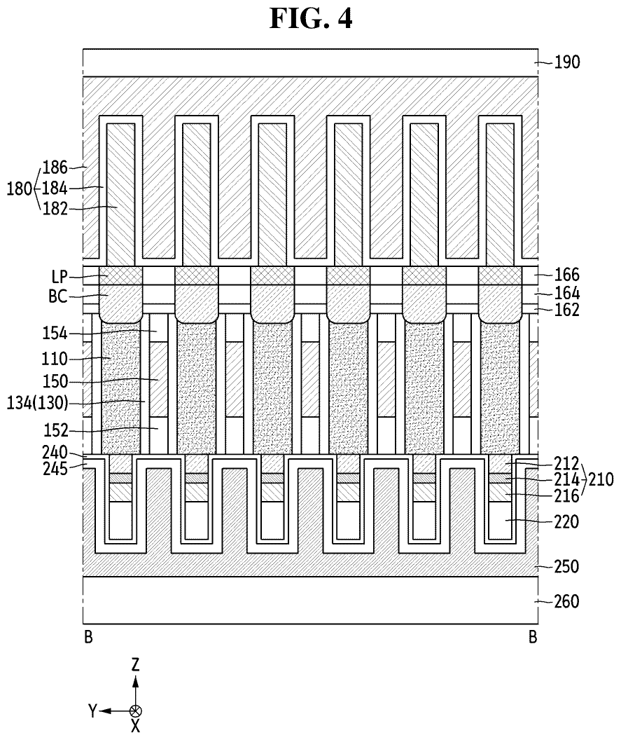

FIG. 1 is an example layout diagram for explaining the semiconductor memory device according to some example embodiments. FIG. 2 is a partially enlarged view for explaining a region R1 of FIG. 1. FIG. 3 is a cross-sectional view taken along A-A of FIG. 1. FIG. 4 is a cross-sectional view taken along B-B of FIG. 1.

Referring to FIGS. 1 to 4, the semiconductor memory device according to some example embodiments includes a plurality of active patterns 110, an insulating pattern 130, a gate electrode 150, a back gate electrode 140, a contact pattern BC, a landing pad LP, a data storage structure 180, an upper insulating film 190, a conductive line 210, a capping film 220, a liner film 240, a spacer film 245, a shield conductive film 250, and a lower insulating film 260.

The plurality of active patterns 110 may be arranged two-dimensionally along a horizontal plane. For example, the active patterns 110 may be disposed in the form of a matrix along a first direction X and a second direction Y that intersect each other.

Each active pattern 110 may extend in a vertical direction. For example, each active pattern 110 may extend long in a third direction Z that intersects the first direction X and the second direction Y. A height of each active pattern 110 extending in the third direction Z may be greater than a width (e.g., width in the first direction X and/or width in the second direction Y) of each active pattern 110. The height of each active pattern 110 may be, but is not limited to, about two to about ten times the width of each active pattern 110. Each active pattern 110 may be provided as a channel region of a vertical channel transistor (VCT). The vertical channel transistor may refer to a structure in which a channel length of a channel layer extends in a vertical direction (e.g., third direction Z).

In some example embodiments, the plurality of active patterns 110 may include a first column 110A and a second column 110B. The first column 110A and the second column 110B may each include a column of active patterns 110 arranged along the second direction Y. The first column 110A and the second column 110B may be alternately arranged along the first direction X.

The active patterns 110 may each include a semiconductor material. For example, the active patterns 110 may each include an elemental semiconductor material such as monocrystalline silicon (monocrystalline Si), polycrystalline silicon (polycrystalline Si), amorphous silicon (amorphous Si), silicon germanium (SiGe), silicon germanium on insulator (SGOI), indium antimonide, lead telluride, indium arsenide, indium phosphide, gallium arsenide or gallium antimonide. However, example embodiments are not limited thereto. Alternatively, for example, the active patterns 110 may each include a metal oxide semiconductor material such as IGZO (indium gallium zinc oxide) or ITZO (indium tin zinc oxide).

Each of the active patterns 110 may include a single layer or multiple layers of semiconductor material. In some example embodiments, each of the active patterns 110 may include a single crystal semiconductor material. As an example, each of the active patterns 110 may include single crystal silicon.

The insulating pattern 130 may extend long in the second direction Y. The insulating patterns 130 may be spaced apart from one another in the first direction X, and extend side by side (or parallel) in the second direction Y. In some example embodiments, the plurality of insulating patterns 130 may be spaced apart from one another in the first direction X at an equal interval.

The insulating pattern 130 may surround a side surface of each of the active patterns 110. For example, one insulating pattern 130 may surround a side surface of each of the active patterns 110 of the first column 110A, and the other insulating pattern 130 may surround a side surface of each of the active patterns 110 of the second column 110B.

The insulating pattern 130 may include a first insulating film 132 and a second insulating film 134. Although an interface between the first insulating film 132 and the second insulating film 134 is only shown to be present, this is merely example. It goes without saying that the interface between the first insulating film 132 and the second insulating film 134 may not be present in some cases.

The first insulating film 132 may be disposed on the side surface of each active pattern 110. The first insulating film 132 may be interposed between the back gate electrode 140 and each active pattern 110. For example, as shown in FIG. 2, each active pattern 110 may include a first side surface 110S1 and a second side surface 110S2 that are opposite to each other in the first direction X. The first insulating film 132 may be disposed on the first side surface 110S1 of each active pattern 110. In some example embodiments, each active pattern 110 may be in direct contact with the first insulating film 132.

The first insulating film 132 may extend long in the second direction Y. For example, as shown in FIG. 2, the active patterns 110 may include a first active pattern 1101 and a second active pattern 1102 that are spaced apart from each other in the second direction Y. The first insulating film 132 may extend long in the second direction Y along the first side surface 110S1 of the first active pattern 1101 and the first side surface 110S1 of the second active pattern 1102.

The first insulating film 132 may include a recess 132R that is adjacent to each active pattern 110 and recessed inward. For example, as shown in FIG. 2, the recess 132R may be formed by being recessed from the first side surface 110S1 to the inside of the first insulating film 132 between the first active pattern 1101 and the second active pattern 1102.

The first insulating film 132 may include, but is not limited to, at least one of silicon oxide, silicon oxynitride, and a high-k material having a higher dielectric constant than silicon oxide or a combination thereof. However, example embodiments are not limited thereto. The high-k material may include at least one of a metal oxide or a metal oxynitride, for example, but is not limited to, HfO₂, HfSiO, HfSiON, HfTaO, HfTiO, HfZrO, ZrO₂, Al₂O₃ or a combination thereof. As an example, the first insulating film 132 may include a silicon oxide film.

In some example embodiments, the recess 132R may include a concave face recessed toward the gate electrode 150.

In some example embodiments, a depth D1 at which the recess 132R is formed in the first direction X may be smaller than a thickness T1 of the first insulating film 132 in the first direction X. Here, the depth D1 of the recess 132R means the maximum depth at which the recess 132R is formed in the first direction X on the basis of the first side surface 110S1. In other words, a depth D1 of the recess 132R may be a distance in the first direction X from the first side surface 110S1 of the first active pattern 1101 to the furthest distance the recess 132R extends towards the back gate electrode 140.

The second insulating film 134 may be disposed on the side surfaces of each active pattern 110. The second insulating film 134 may be interposed between the gate electrode 150 and each active pattern 110. For example, as shown in FIG. 2, the second insulating film 134 may surround the side surface of each active pattern 110 along which the first insulating film 132 does not extend. In some example embodiments, each active pattern 110 may be in direct contact with the second insulating film 134.

In some example embodiments, the second insulating film 134 may further extend along the recess 132R of the first insulating film 132. For example, the second insulating film 134 may conformally extend along the profile of the side surface of each active pattern 110 except for the first side surface 110S1, and the profile of the recess 132R.

The second insulating film 134 may include, but is not limited to, at least one of silicon oxide, silicon oxynitride, and a high-k material having a higher dielectric constant than silicon oxide, or a combination thereof. However, example embodiments are not limited thereto. The high-k material may include, but is not limited to, at least one of metal oxide or metal oxynitride, for example, HfO₂, HfSiO, HfSiON, HfTaO, HfTiO, HfZrO, ZrO₂, Al₂O₃ or a combination thereof. As an example, the second insulating film 134 may include a silicon oxide film.

The gate electrode 150 may be disposed on the side surfaces of each active pattern 110. For example, as shown in FIG. 2, the gate electrode 150 may be disposed on the second side surface 110S2 of each active pattern 110. The gate electrode 150 may be spaced apart from each active pattern 110 by the second insulating film 134. The second insulating film 134 may be provided as a gate dielectric film of the gate electrode 150.

The gate electrode 150 may intersect each active pattern 110. For example, the gate electrode 150 may extend long in the second direction Y. The plurality of gate electrodes 150 may be spaced apart from each other in the first direction X and extend side by side (or parallel) in the second direction Y. The gate electrode 150 may be provided as a word line of the semiconductor memory device according to some example embodiments.

A part of the gate electrode 150 may be interposed between the active patterns 110 arranged along the second direction Y. For example, as shown in FIG. 2, the gate electrode 150 may include a first gate portion 1501 and a second gate portion 1502. The first gate portion 1501 may be spaced apart from each active pattern 110 in the first direction X. The second gate portion 1502 may be spaced apart from each active pattern 110 in the second direction Y. As an example, the second gate portion 1502 may be interposed between the first active pattern 1101 and the second active pattern 1102. The second gate portion 1502 may have a shape that extends from the first gate portion 1501 and protrudes toward the recess 132R.

In some example embodiments, the second gate portion 1502 of the gate electrode 150 may extend along the profile of the recess 132R. For example, the second gate portion 1502 of the gate electrode 150 may be in direct contact with a part of the second insulating film 134 that conformally extends along the profile of the recess 132R. In some example embodiments, the gate electrode 150 may conformally extend along the profile of the second insulating film 134.

In some example embodiments, the second gate portion 1502 of the gate electrode 150 may include a convex surface 150C that is convex toward the recess 132R. In some example embodiments, the convex surface 150C may form a smooth curved surface such that the second gate portion 1502 of the gate electrode 150 does not have a sharp edge. For example, a magnitude of a slope of a tangent line that abuts on the convex surface 150C may be continuous across the convex surface 150C.

In some example embodiments, each active pattern 110 may entirely overlap the second gate portion 1502 of the gate electrode 150 in the second direction Y. For example, as shown in FIG. 2, the maximum length D2 at which the second gate portion 1502 of the gate electrode 150 extends in the first direction X may be greater than or equal to the width H1 of the first active pattern 1101 in the first direction X, on the basis of the second side surface 110S2 of the first active pattern 1101. In other words, a maximum length D2 of the second gate portion 1502 of the gate electrode 150 may be a distance from the second side surface 110S2 of the first active pattern 1101 in the first direction X to the furthest distance the second gate portion 1502 extends towards the first insulating film 132. As an example, the depth D1 at which the recess 132R is formed in the first direction X may be equal to (or substantially equal to) the thickness T2 of the second insulating film 134 in the first direction X. In this case, an end of the second gate portion 1502 in the first direction X may be coplanar (and/or substantially coplanar) with the first side surface 110S1 of the first active pattern 1101. In this specification, the term “same” means not only exactly the same thing but also includes a slight difference that may occur due to a process margin or the like.

The gate electrode 150 may include a conductive material, for example, at least one of doped polysilicon, a metal, a conductive metal nitride, a conductive metal silicide, a conductive metal oxide, or a combination thereof. However, example embodiments are not limited thereto. For example, the gate electrode 150 may include, but is not limited to, at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof.

In some example embodiments, the bottom surface of the gate electrode 150 may be formed to be higher than the bottom surface of each active pattern 110. For example, as shown in FIG. 3, a first lower spacer 152 may be formed on the bottom surface of the gate electrode 150. The bottom surface of the first lower spacer 152 may be coplanar (and/or substantially coplanar) with the bottom surface of each active pattern 110. The gate electrode 150 may be spaced apart from the conductive line 210 in the third direction Z by the first lower spacer 152.

In some example embodiments, the upper surface of the gate electrode 150 may be formed to be lower than the upper surfaces of each active patterns 110. For example, as shown in FIG. 3, a first upper spacer 154 may be formed on the upper surface of the gate electrode 150. The upper surface of the first upper spacer 154 may be coplanar (and/or substantially coplanar) with the upper surfaces of each active pattern 110. The gate electrode 150 may be spaced apart from the contact pattern BC and/or the etching stop film 162 in the third direction Z by the first upper spacer 154.

Each of the first lower spacer 152 and the first upper spacer 154 may include an insulating material, for example, but are not limited to, at least one of silicon oxide, silicon nitride, silicon oxynitride, silicon oxycarbonitride, or a combination thereof. Each of the first lower spacer 152 and the first upper spacer 154 may be a single film made of one type of insulating material, or may be a multi-film made of a combination of various types of insulating materials.

In some example embodiments, the gate electrode 150 may include a first gate electrode 150A and a second gate electrode 150B. The first gate electrode 150A may intersect each active pattern 110 of the first column 110A, and the second gate electrode 150B may intersect each active pattern 110 of the second column 110B. For example, the first gate electrode 150A may be disposed on a side surface of the first column 110A opposite to the second column 110B, and the second gate electrode 150B may be disposed on a side surface of the second column 110B opposite to the first column 110A.

The first gate electrode 150A and the second gate electrode 150B may be spaced apart from each other in the first direction X. For example, as shown in FIG. 3, a separation spacer 156 may be formed between the first gate electrode 150A and the second gate electrode 150B. The separation spacer 156 may extend long in the second direction Y to separate the first gate electrode 150A and the second gate electrode 150B in the first direction X.

The back gate electrode 140 may be disposed on the side surfaces of each active pattern 110. For example, as shown in FIG. 2, the back gate electrode 140 may be disposed on the first side surface 110S1 of each active pattern 110. The back gate electrode 140 may be spaced apart from each active pattern 110 by the first insulating film 132. The first insulating film 132 may be provided as a gate dielectric film of the back gate electrode 140.

The back gate electrode 140 may intersect each active pattern 110. For example, the back gate electrode 140 may extend long in the second direction Y. The plurality of back gate electrodes 140 may extend side by side (or parallel) in the second direction, Y while being spaced apart from each other in the first direction X.

The back gate electrode 140 may include a conductive material, for example, at least one of a doped polysilicon, a metal, a conductive metal nitride, a conductive metal silicide, a conductive metal oxide, or a combination thereof. However, example embodiments are not limited thereto. For example, the back gate electrode 140 may include, but is not limited to, at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof.

In some example embodiments, the bottom surface of the back gate electrode 140 may be formed to be higher than the bottom surface of each active pattern 110. For example, as shown in FIG. 3, a second lower spacer 142 may be formed on the bottom surface of the back gate electrode 140. The bottom surface of the second lower spacer 142 may be coplanar (and/or substantially coplanar) with the bottom surface of each active pattern 110. The back gate electrode 140 may be spaced apart from the conductive line 210 in the third direction Z by the second lower spacer 142.

In some example embodiments, the upper surface of the back gate electrode 140 may be formed to be lower than the upper surface of each active pattern 110. For example, as shown in FIG. 3, a second upper spacer 144 may be formed on the upper surface of the back gate electrode 140. The upper surface of the second upper spacer 144 may be coplanar (and/or substantially coplanar) with the upper surface of each active pattern 110. The back gate electrode 140 may be spaced apart from the contact pattern BC and/or the etching stop film 162 in the third direction Z by the second upper spacer 144.

Each of the second lower spacer 142 and the second upper spacer 144 may include an insulating material, for example, but are not limited to, at least one of silicon oxide, silicon nitride, silicon oxynitride, silicon oxycarbonitride, or a combination thereof. However, example embodiments are not limited thereto. Each of the second lower spacer 142 and the second upper spacer 144 may be a single film made of one type of insulating material, or a multi-layer film made of a combination of various types of insulating materials.

In some example embodiments, the first column 110A and the second column 110B may share one back gate electrode 140. For example, the first column 110A may be disposed on one side surface of the back gate electrode 140, and the second column 110B may be disposed on the other side surface of the back gate electrode 140.

The contact pattern BC may be disposed on the upper surface of each active pattern 110. The contact pattern BC may be connected to each active pattern 110. For example, an etching stop film 162 and a first interlayer insulating film 164 may be sequentially stacked on the upper surface of the first interlayer insulating film 160. The contact pattern BC penetrates the etching stop film 162 and the first interlayer insulating film 164, and may come into contact with the upper surface of each active pattern 110.

The contact pattern BC may include a conductive material, for example, but is not limited to, at least one of doped polysilicon, a conductive metal nitride, a conductive metal silicon nitride, a metal carbonitride, a conductive metal silicide, a conductive metal oxide, a two-dimensional material, a metal, or a combination thereof. However, example embodiments are not limited thereto.

The landing pad LP may be disposed on the upper surface of the contact pattern BC. The landing pad LP may be connected to the contact pattern BC. For example, a second interlayer insulating film 166 may be stacked on the upper surface of the first interlayer insulating film 164. The landing pad LP penetrates the second interlayer insulating film 166, and may come into contact with the upper surface of the contact pattern BC.

The landing pad LP may include a conductive material, for example, but is not limited to, at least one of doped polysilicon, a conductive metal nitride, a conductive metal silicon nitride, a metal carbonitride, a conductive metal silicide, a conductive metal oxide, a two-dimensional material, a metal, or a combination thereof.

The data storage structure 180 may be disposed on the upper surface of the landing pad LP and the upper surface of the second interlayer insulating film 166. The data storage structure 180 may be connected to the landing pad LP. The data storage structure 180 may be connected to the active patterns 110 through the contact pattern BC and the landing pad LP. The data storage structure 180 is controlled by the conductive line 210 provided as a bit line and the gate electrode 150 provided as a word line, and may store data in the unit memory cell corresponding to each active pattern 110.

In some example embodiments, the data storage structure 180 may be a capacitor. For example, the data storage structure 180 may include a lower electrode 182, a capacitor dielectric film 184, and an upper electrode 186 that are sequentially stacked on the landing pad LP. The data storage structure 180 may store charges in the capacitor dielectric film 184, using a potential difference that occurs between the lower electrode 182 and the upper electrode 186.

Each of the lower electrode 182 and the upper electrode 186 may include, but is not limited to, a doped polysilicon, a metal, or a metal nitride. Furthermore, the capacitor dielectric film 184 may include, but is not limited to, a silicon oxide or a high dielectric constant material.

The upper insulating film 190 may be stacked on the data storage structure 180. The upper insulating film 190 may cover at least a part of the data storage structure 180. The upper insulating film 190 may include, for example, but is not limited to, at least one of silicon oxide, silicon nitride, silicon oxynitride, silicon oxycarbonitride or a combination thereof.

The conductive line 210 may be disposed on the bottom surface of each active pattern 110. The conductive line 210 may intersect the gate electrode 150. For example, the conductive line 210 may extend long in the first direction X. The plurality of conductive lines 210 are spaced apart from each other in the second direction Y, and may extend side by side (or to be parallel) in the first direction X. Each conductive line 210 may be commonly connected to one row of active patterns 110 arranged along the first direction X. The conductive line 210 may be provided as a bit line of a semiconductor memory device according to some example embodiments.

In some example embodiments, the conductive line 210 may include a first conductive film 212, a second conductive film 214, and a third conductive film 216 that are sequentially stacked on the bottom surface of each active pattern 110. The first conductive film 212, the second conductive film 214, and the third conductive film 216 may each include a conductive material, for example, but are not limited to, at least one of polysilicon, TiN, TiSiN, tungsten, tungsten silicide, or a combination thereof. As an example, the first conductive film 212 may include a polysilicon film (poly-Si), the second conductive film 214 may include a TiSiN film, and the third conductive film 216 may include a tungsten film (W).

The capping film 220 may extend along the bottom surface of the conductive line 210. The capping film 220 may extend long in the first direction X. The capping film 220 may include an insulating material, for example, but is not limited to, at least one of silicon oxide, silicon nitride, silicon oxynitride, silicon oxycarbonitride, and a combination thereof. As an example, the capping film 220 may include a silicon nitride film.

The liner film 240 may be stacked under the conductive line 210 and the capping film 220. For example, the liner film 240 may extend conformally along the profiles of the side surface and bottom surface of the capping film 220, the side surface of the conductive line 210, the bottom surface of the insulating pattern 130, the bottom surface of the first lower spacer 152, and the bottom surface of the second lower spacer 142.

The liner film 240 may include an insulating material, for example, but is not limited to, at least one of silicon oxide, silicon nitride, silicon oxynitride, silicon oxycarbonitride, and a combination thereof. As an example, the liner film 240 may include a silicon nitride film.

The spacer film 245 may be stacked under the liner film 240. For example, the spacer film 245 may conformally extend along the profile of the side surface and bottom surface of the liner film 240.

The spacer film 245 may include an insulating material, for example, but is not limited to, at least one of silicon oxide, silicon nitride, silicon oxynitride, silicon oxycarbonitride, and a combination thereof. As an example, the spacer film 245 may include a silicon oxide film.

A shield conductive film 250 may be stacked under the spacer film 245. At least a part of the shield conductive film 250 may be interposed between the conductive lines 210 disposed along the second direction Y. For example, as shown in FIG. 4, the shield conductive film 250 may be formed to fill at least a part of the region between one conductive line 210 and the other conductive line 210. The shield conductive film 250 may be spaced apart from the conductive line 210 by the liner film 240 and/or the spacer film 245.

The shield conductive film 250 may include a conductive material, for example, at least one of doped polysilicon, a metal, a conductive metal nitride, a conductive metal silicide, a conductive metal oxide, or a combination thereof. However, example embodiments are not limited thereto. The shield conductive film 250 may reduce coupling noise between the conductive lines 210 in the second direction Y. For example, a desired (and/or alternatively predetermined) bias voltage (e.g., a ground voltage) may be applied to the shield conductive film 250.

The lower insulating film 260 may be stacked under the shield conductive film 250. The lower insulating film 260 may cover at least a part of the shield conductive film 250. The lower insulating film 260 may include, but is not limited to, at least one of a silicon oxide, a silicon nitride, a silicon oxynitride, a silicon oxycarbonitride, or a combination thereof.

In a semiconductor memory device including a vertical channel transistor (VCT), a so-called tri-gate structure that surrounds three sides of the gate electrode has been proposed to improve gate controllability, which means the controllability of the gate electrode. In the tri-gate structure, the width (e.g., H1 of FIG. 2) of the channel is one of the factors that determine the gate controllability. However, as semiconductor memory devices are continuously integrated, the width of the channel decreases, and therefore, the gate controllability desired for the tri-gate structure is not ensured.

The semiconductor memory device according to some example embodiments may improve the gate controllability of the tri-gate structure by including an insulating pattern 130 that includes a recess 132R. Specifically, as described above, the first insulating film 132 of the insulating pattern 130 may include a recess 132R recessed inward, and the second gate portion 1502 of the gate electrode 150 may have a shape that protrudes toward the recess 132R. Such a gate electrode 150 may increase the opposite area with each active pattern 110, thereby improving the gate controllability of the gate electrode 150. Furthermore, in the semiconductor memory device according to some example embodiments, the gate controllability of the gate electrode 150 is not limited to the width (e.g., H1 of FIG. 2) of each active pattern 110, and may be improved with an increase in the depth (e.g., D1 of FIG. 2) at which the recess 132R is formed. This makes it possible to provide a semiconductor memory device with improved performance and/or integration.

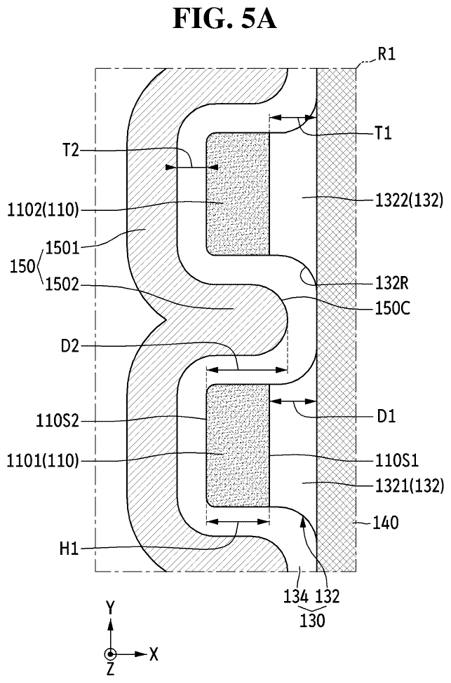

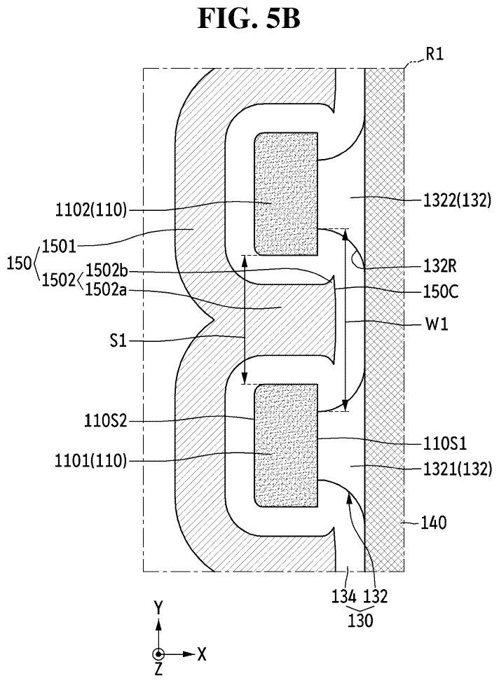

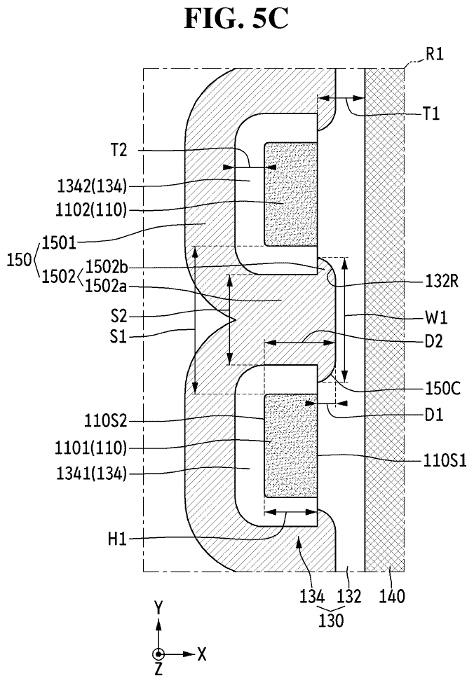

FIGS. 5A to 5C are various partially enlarged views for explaining a region R1 of FIG. 1. For convenience of explanation, repeated parts of contents explained above using FIGS. 1 to 4 will be briefly explained or omitted.

Referring to FIGS. 1 and 5A, in the semiconductor memory device according to some example embodiments, a part of the second gate portion 1502 overlaps the first insulating film 132 in the second direction Y.

For example, on the basis of the second side surface 110S2 of the first active pattern 1101, the maximum length D2 of the second gate portion 1502 of the gate electrode 150 extending in the first direction X may be greater than the width H1 of the first active pattern 1101 in the first direction X. As an example, the depth D1 at which the recess 132R is formed in the first direction X may be greater than the thickness T2 of the second insulating film 134 in the first direction X. In this case, the end of the second gate portion 1502 in the first direction X may further protrude in the first direction X beyond the first side surface 110S1 of the first active pattern 1101.

In some example embodiments, the second insulating film 134 may be in contact with the back gate electrode 140. For example, the depth D1 at which the recess 132R is formed in the first direction X may be equal to (or substantially equal to) the thickness T1 of the first insulating film 132. The first insulating film 132 may include a first sub-insulating film 1321 and a second sub-insulating film 1322 separated from each other in the second direction Y by the recess 132R. The second insulating film 134 may further extend along the side surface of the back gate electrode 140 between the first sub-insulating film 1321 and the second sub-insulating film 1322. The gate electrode 150 and the back gate electrode 140 may be separated from each other by the second insulating film 134 between the first active pattern 1101 and the second active pattern 1102.

Referring to FIGS. 1 and 5B, in the semiconductor memory device according to some example embodiments, a part of the recess 132R overlaps a part of each active pattern 110 in the first direction X.

For example, the width W1 of the recess 132R in the second direction Y may be greater than a distance S1 by which the first active pattern 1101 and the second active pattern 1102 are spaced apart in the second direction Y. Although FIG. 5B only shows that the second insulating film 134 is in contact with the back gate electrode 140, this is merely example. In some example embodiments, unlike the shown example, the depth D1 at which the recess 132R is formed in the first direction X may be smaller than the thickness T1 of the first insulating film 132.

In some example embodiments, the second gate portion 1502 of the gate electrode 150 may include a first portion 1502a and a second portion 1502b. The first portion 1502a may extend from the first gate portion 1501 in the first direction X. The second portion 1502b may protrude from the first portion 1502a toward the first active pattern 1101 and/or the second active pattern 1102. The second portion 1502b may overlap the first insulating film 132 in the second direction Y. For example, the second portion 1502b may protrude in the second direction Y from a part of the first portion 1502a that overlaps the first insulating film 132 in the second direction Y. Such a gate electrode 150 may further improve the gate controllability of the gate electrode 150 by increasing the opposite area with each active pattern 110.

Referring to FIGS. 1 and 5C, in the semiconductor memory device according to some example embodiments, the second gate portion 1502 of the gate electrode 150 is in direct contact with the first insulating film 132.

For example, the second insulating film 134 may include a third sub-insulating film 1341 and a fourth sub-insulating film 1342 that are separated from each other in the second direction Y. The third sub-insulating film 1341 may surround the side surfaces of the first active pattern 1101 along which the first insulating film 132 does not extend, and the fourth sub-insulating film 1342 may surround the side surface of the second active patterns 1102 along which the first insulating film 132 does not extend. The third sub-insulating film 1341 may be interposed between the first active pattern 1101 and the gate electrode 150, and the fourth sub-insulating film 1342 may be interposed between the second active pattern 1102 and the gate electrode 150. The second gate portion 1502 of the gate electrode 150 may be in direct contact with the recess 132R of the first insulating film 132 between the third sub-insulating film 1341 and the fourth sub-insulating film 1342.

In some example embodiments, the width W1 of the recess 132R in the second direction Y may be greater than the distance S2 by which the third sub-insulating film 1341 and the fourth sub-insulating film 1342 are spaced apart in the second direction Y.

In some example embodiments, the width W1 of the recess 132R in the second direction Y may be smaller than the distance S1 by which the first active pattern 1101 and the second active pattern 1102 are spaced apart in the second direction Y.

In some example embodiments, the second insulating film 134 may include an oxide of the semiconductor material included in each active pattern 110. As an example, when each of the first active pattern 1101 and the second active pattern 1102 is a silicon pattern, each of the third sub-insulating film 1341 and the fourth sub-insulating film 1342 may include a silicon oxide film.

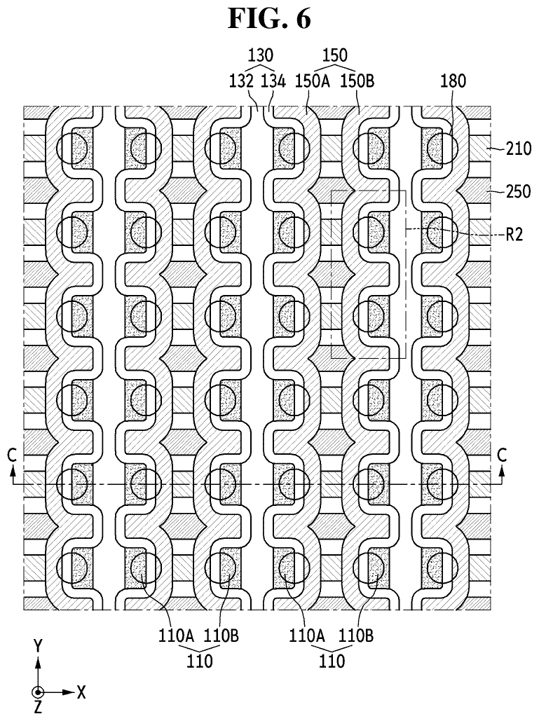

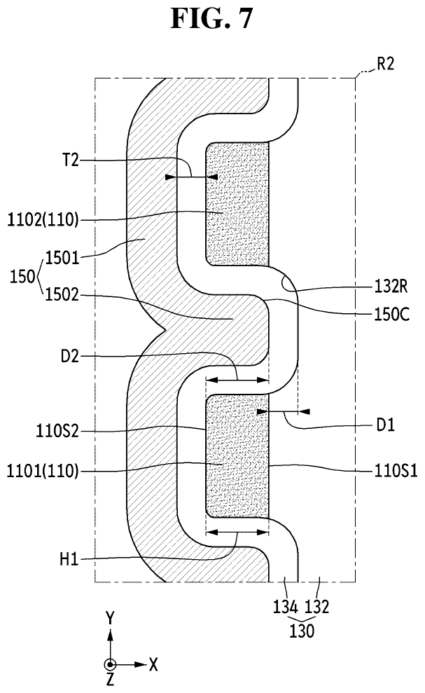

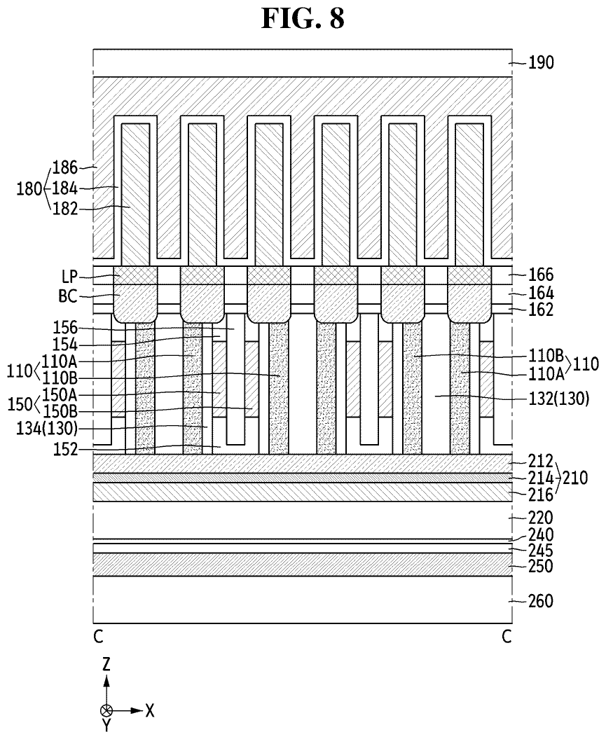

FIG. 6 is an example layout diagram for explaining a semiconductor memory device according to some example embodiments. FIG. 7 is a partially enlarged view for explaining a region R2 of FIG. 6. FIG. 8 is a cross-sectional view taken along C-C of FIG. 6. For convenience of explanation, repeated parts of contents explained above using FIGS. 1 to 4 will be briefly described or omitted.

Referring to FIGS. 6 to 8, in the semiconductor memory device according to some example embodiments, the first column 110A and the second column 110B share one first insulating film 132.

For example, the back gate electrode 140 described above using FIGS. 1 to 4 may be omitted. In some example embodiments, the first column 110A may be in contact with one side surface of one first insulating film 132, and the second column 110B may be in contact with the other side surface of the one first insulating films 132.

In some example embodiments, each active pattern 110 may entirely overlap the second gate portion 1502 of the gate electrode 150 in the second direction Y. For example, as shown in FIG. 7, the maximum length D2 at which the second gate portion 1502 of the gate electrode 150 extends in the first direction X may be greater than or equal to the width H1 of the first active pattern 1101 in the first direction X, on the basis of the second side surface 110S2 of the first active pattern 1101. In other words, a maximum length D2 of the second gate portion 1502 of the gate electrode 150 in the first direction X may be a distance from the second side surface 110S2 of the first active pattern 1101 to the furthest distance the second gate portion 1502 extends towards the first insulating film 132.

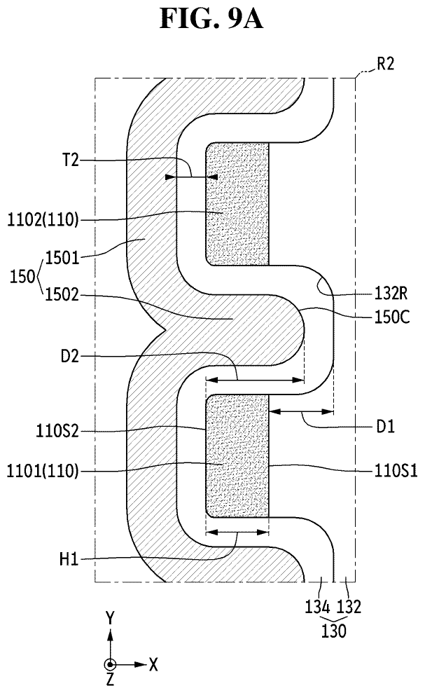

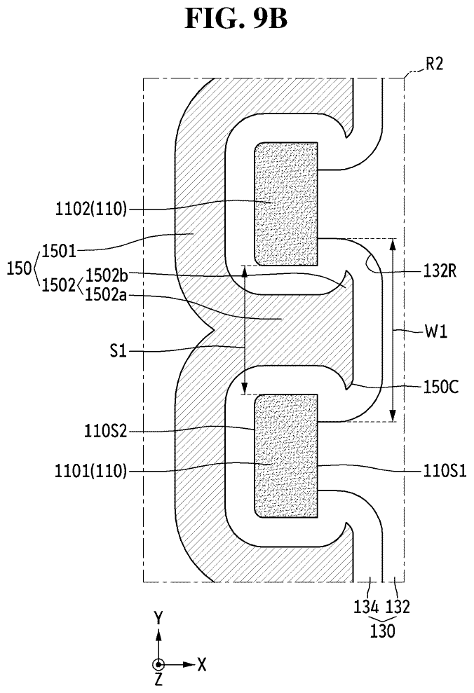

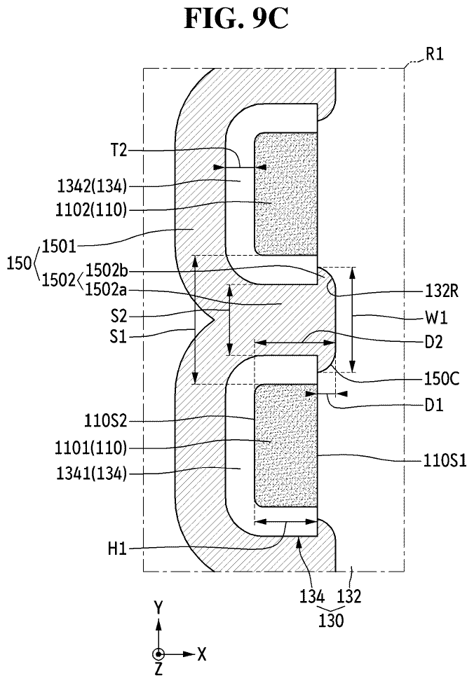

FIGS. 9A to 9C are various other partially enlarged views for explaining a region R2 of FIG. 6. For convenience of explanation, repeated parts of contents explained above using FIGS. 1 to 8 will be briefly explained or omitted.

Referring to FIGS. 6 and 9A, in the semiconductor memory device according to some example embodiments, a part of the second gate portion 1502 overlaps the first insulating film 132 in the second direction Y. The semiconductor memory device according to FIG. 9A may be similar to the semiconductor memory device described above using FIG. 5A, and therefore the detailed description thereof will not be provided below.

Referring to FIGS. 6 and 9B, in the semiconductor memory device according to some example embodiments, a part of the recess 132R overlaps a part of each active pattern 110 in the first direction X. The semiconductor memory device according to FIG. 9B may be similar to the semiconductor memory device described above referring to FIG. 5B, and therefore the detailed description thereof will not be provided below.

Referring to FIGS. 1 and 9C, in the semiconductor memory device according to some example embodiments, the second gate portion 1502 of the gate electrode 150 is in direct contact with the first insulating film 132. The semiconductor memory device according to FIG. 9C may be similar to the semiconductor memory device described above using FIG. 5C, and therefore the detailed description thereof will not be provided below.

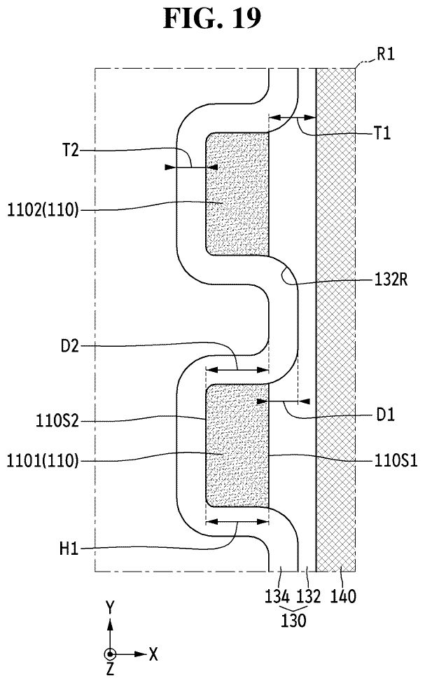

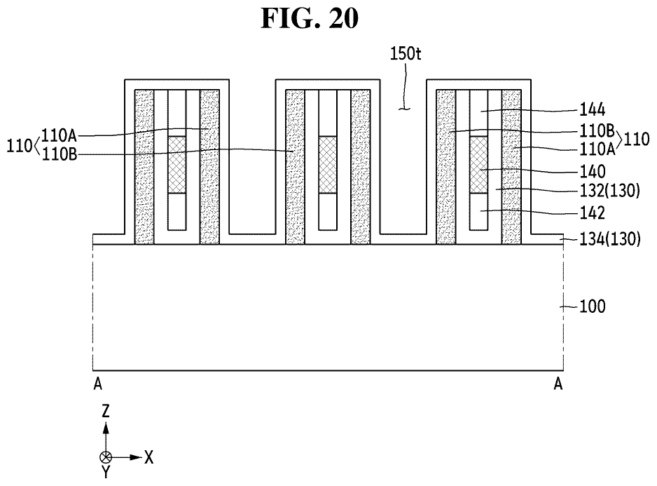

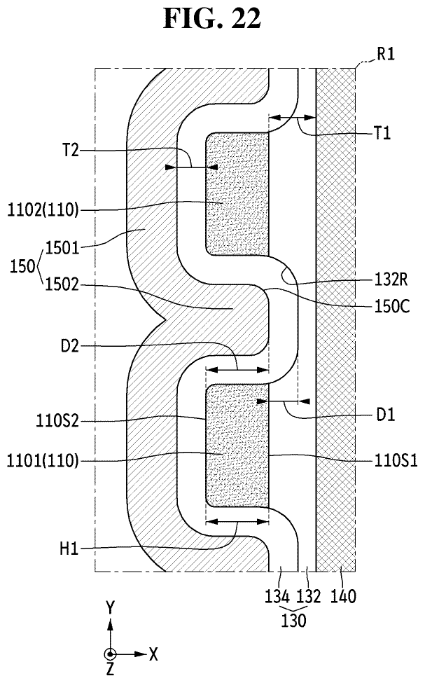

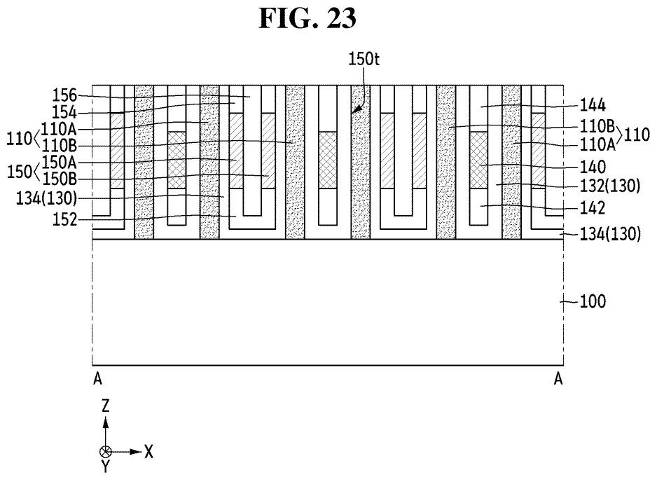

Hereinafter, a method for fabricating a semiconductor memory device according to some example embodiments will be described referring to FIGS. 1 to 34.

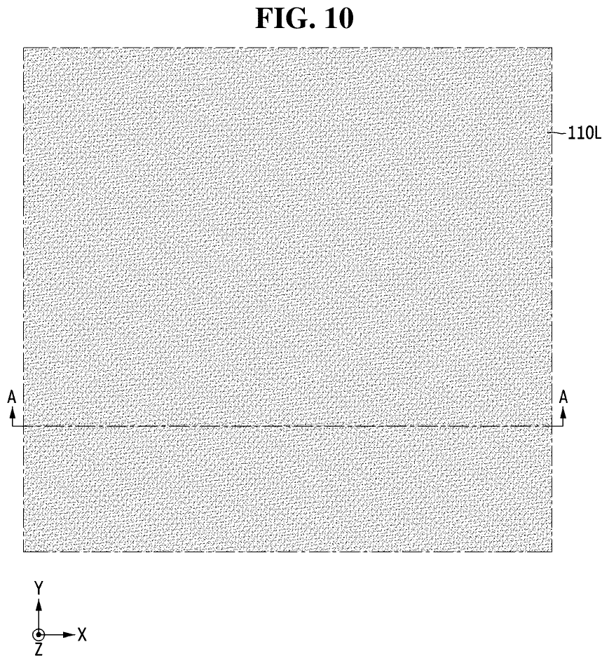

FIGS. 10 to 30 are intermediate step diagrams for describing the method for fabricating the semiconductor memory device according to some example embodiments. For convenience of explanation, repeated parts of contents explained above using FIGS. 1 to 9C will be briefly explained or omitted.

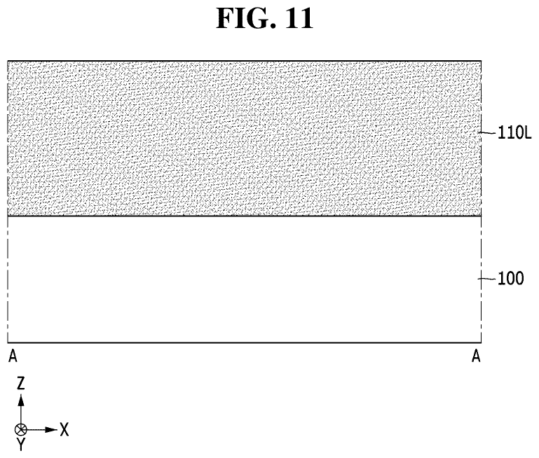

Referring to FIGS. 10 and 11, an active film 110L is formed on a base substrate 100.

The base substrate 100 may be bulk silicon or silicon-on-insulator (SOI). The base substrate 100 may be a silicon substrate or may include other materials, for example, silicon germanium, gallium arsenide, silicon germanium on insulator (SGOI), indium antimonide, lead telluride, indium arsenide, indium phosphide or gallium antimonide. However, example embodiments are not limited thereto. Alternatively, the base substrate 100 may be one in which an epitaxial layer is formed on the base substrate, and may be a ceramic substrate, a quartz substrate, a display glass substrate, or the like.

The active film 110L may include a semiconductor material. For example, the active film 110L may include an elemental semiconductor material such as monocrystalline silicon (monocrystalline Si), polycrystalline silicon (polycrystalline Si), amorphous silicon (amorphous Si), silicon germanium (SiGe), silicon germanium on insulator (SGOI), indium antimonide, lead telluride, indium arsenide, indium phosphide, gallium arsenide, or gallium antimonide. However, example embodiments are not limited thereto. Alternatively, for example, the active film 110L may include a metal oxide semiconductor material such as indium gallium zinc oxide (IGZO) or indium tin zinc oxide (ITZO).

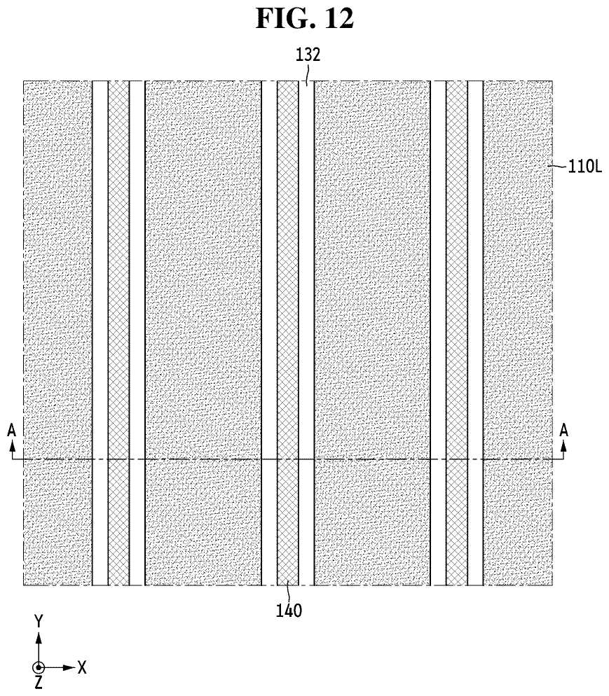

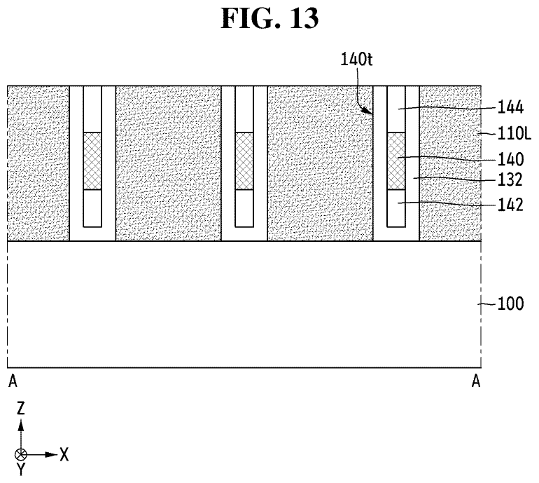

Referring to FIGS. 12 and 13, a first insulating film 132 and a back gate electrode 140 are formed in the active film 110L.

For example, a first trench 140t extending long in the second direction Y may be formed inside the active film 110L. The first insulating film 132 may be formed inside the first trench 140t. The first insulating film 132 may conformally extend along the bottom surface and side surface of the first trench 140t. Next, a second lower spacer 142, a back gate electrode 140, and a second upper spacer 144 may be sequentially formed on the first insulating film 132. The second lower spacer 142, the back gate electrode 140, and the second upper spacer 144 may fill the region of the first trench 140t that remains after the first insulating film 132 is filled.

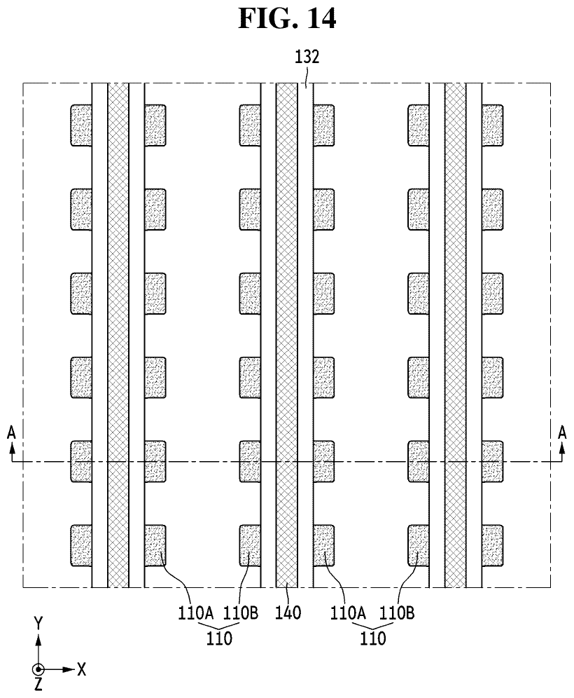

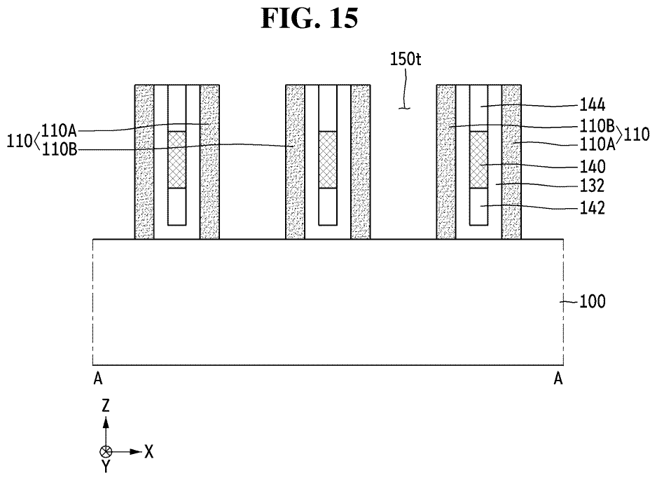

Referring to FIGS. 14 and 15, a plurality of active patterns 110 are formed.

For example, a patterning process may be performed on the active film 110L of FIGS. 12 and 13 to form a plurality of active patterns 110 arranged two-dimensionally along a horizontal plane (e.g., an XY plane).

In some example embodiments, the plurality of active patterns 110 and the first insulating film 132 may define a second trench 150t extending long in the second direction Y. For example, the second trench 150t may extend long in the Y direction between one first insulating film 132 coming into contact with the first column 110A and the other first insulating film 132 coming into contact with the second column 110B.

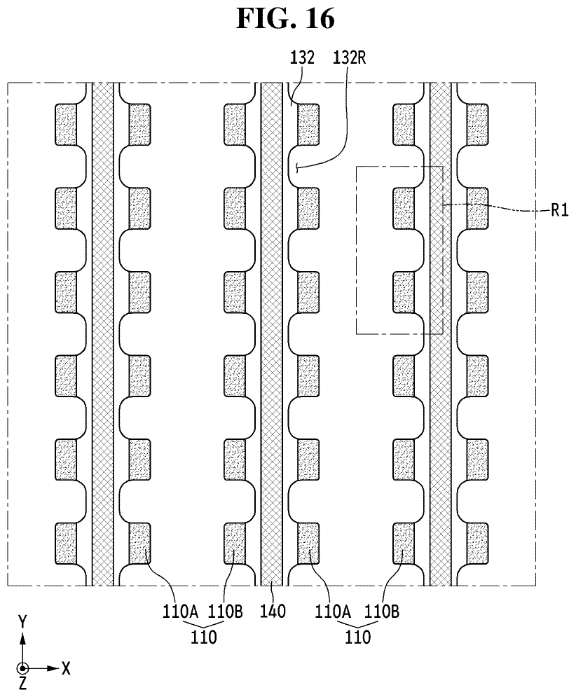

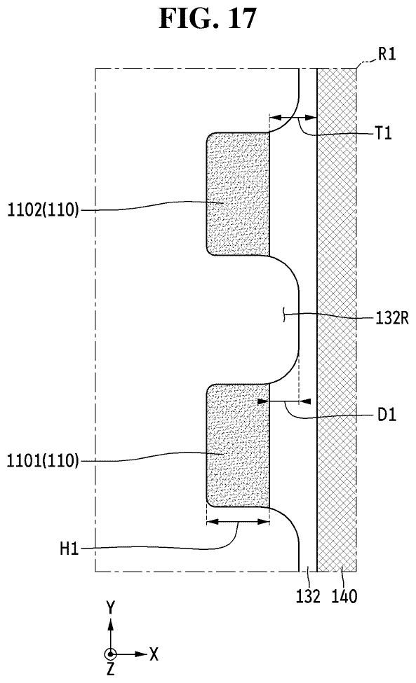

Referring to FIGS. 16 and 17, a recess 132R is formed inside the first insulating film 132.

For example, a recess process may be performed on the first insulating film 132. As the recess process is performed, a part of the first insulating film 132 exposed from the plurality of active patterns 110 may be recessed inward. Accordingly, the recess 132R adjacent to each active pattern 110 may be formed. For example, as shown in FIG. 17, the recess 132R may be recessed from the first side surface 110S1 toward the inside of the first insulating film 132 between the first active pattern 1101 and the second active pattern 1102.

In some example embodiments, a depth D1 at which the recess 132R is formed in the first direction X may be smaller than a thickness T1 of the first insulating film 132 in the first direction X.

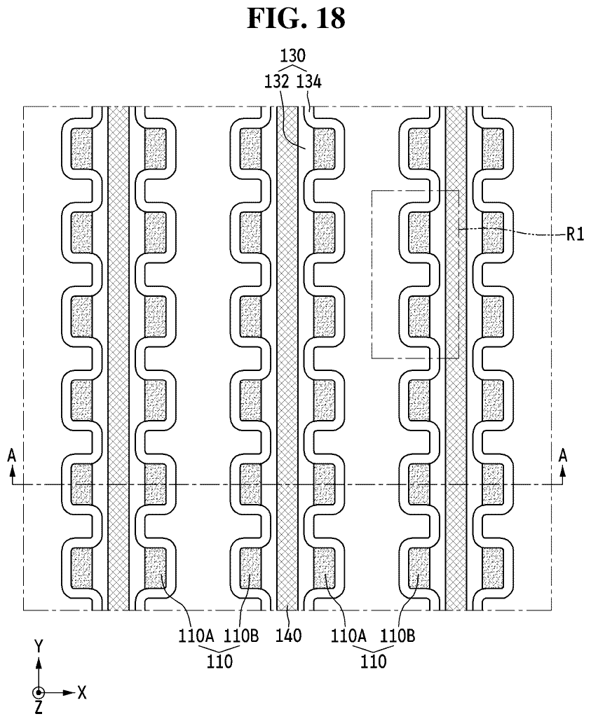

Referring to FIGS. 18 to 20, the second insulating film 134 is formed.

The second insulating film 134 may surround the side surfaces of each active pattern 110 along which the first insulating film 132 does not extend. For example, the second insulating film 134 may conformally extend along the profile of the side surfaces of each active pattern 110 except the first side surface 110S1. Accordingly, an insulating pattern 130 including the first insulating film 132 and the second insulating film 134 may be formed.

In some example embodiments, the second insulating film 134 may be formed inside the second trench 150t. The second insulating film 134 may conformally extend along the bottom surface and the side surface of the second trench 150t.

In some example embodiments, the second insulating film 134 may be formed by a deposition process. The deposition process may include, for example, but is not limited to, an atomic layer deposition (ATOM) method or a chemical vapor deposition (CVD) method. In such a case, the second insulating film 134 may extend further along the recess 132R of the first insulating film 132.

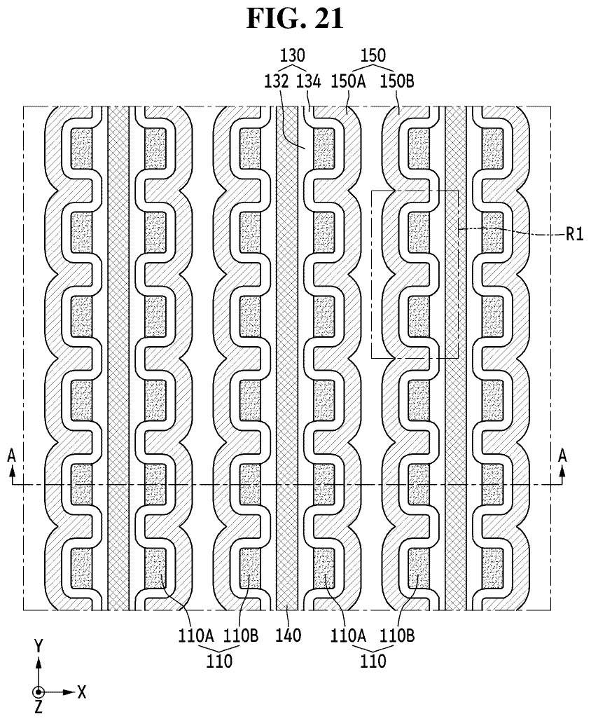

Referring to FIGS. 21 to 23, the gate electrode 150 is formed.

For example, the first lower spacer 152, the gate electrode 150, and the first upper spacer 154 may be sequentially formed on the second insulating film 134. The gate electrode 150 may be spaced apart from each active pattern 110 by the second insulating film 134.

In some example embodiments, a separation spacer 156 may be formed inside the first lower spacer 152, the gate electrode 150, and the first upper spacer 154. The separation spacer 156 may extend long in the second direction Y, and cut the gate electrode 150 in the first direction X. Accordingly, the gate electrode 150 including the first gate electrode 150A and the second gate electrode 150B may be formed.

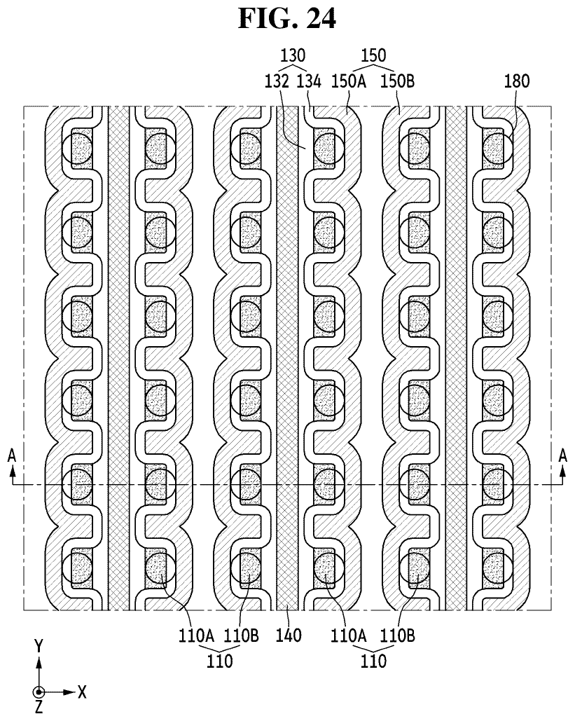

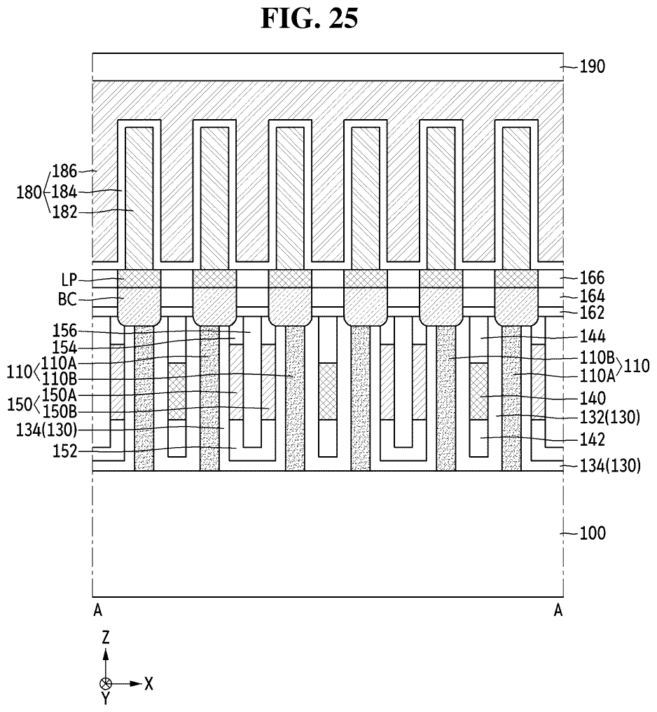

Referring to FIGS. 24 and 25, the contact pattern BC, the landing pad LP, and the data storage structure 180 are formed.

For example, the etching stop film 162 and the first interlayer insulating film 164 may be stacked sequentially on the plurality of active patterns 110, the insulating pattern 130, the first upper spacer 154, and the second upper spacer 144. The contact pattern BC penetrates the etching stop film 162 and the first interlayer insulating film 164, and may be connected to the respective active patterns 110.

Next, the second interlayer insulating film 166 may be stacked on the first interlayer insulating film 164. The landing pads LP penetrates the second interlayer insulating film 166, and may be connected to the contact pattern BC.

Next, the data storage structure 180 may be formed on the landing pads LP and the second interlayer insulating film 166. The data storage structure 180 may include a lower electrode 182, a capacitor dielectric film 184, and an upper electrode 186, which are sequentially stacked on the landing pads LP. After forming the data storage structure 180, the upper insulating film 190 that covers at least a part of the data storage structure 180 may be formed.

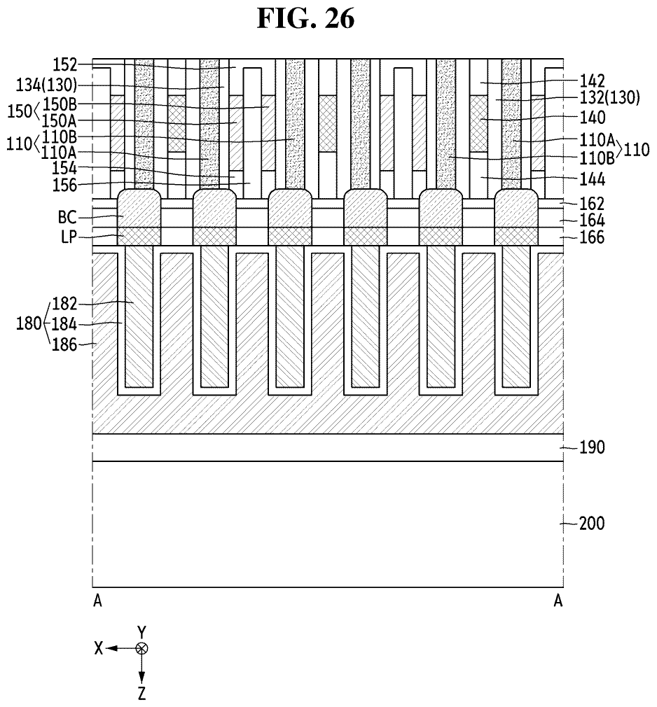

Referring to FIG. 26, the base substrate 100 is removed.

For example, a carrier substrate 200 may be attached onto the result product of FIG. 25. After the carrier substrate 200 is attached, the result product of FIG. 25 may be inverted. Next, a thinning process may be performed on the base substrate 100. The thinning process may include, but is not limited to, a back grinding process on the back face of the base substrate 100. As the thinning process is performed, each active pattern 110 may be exposed.

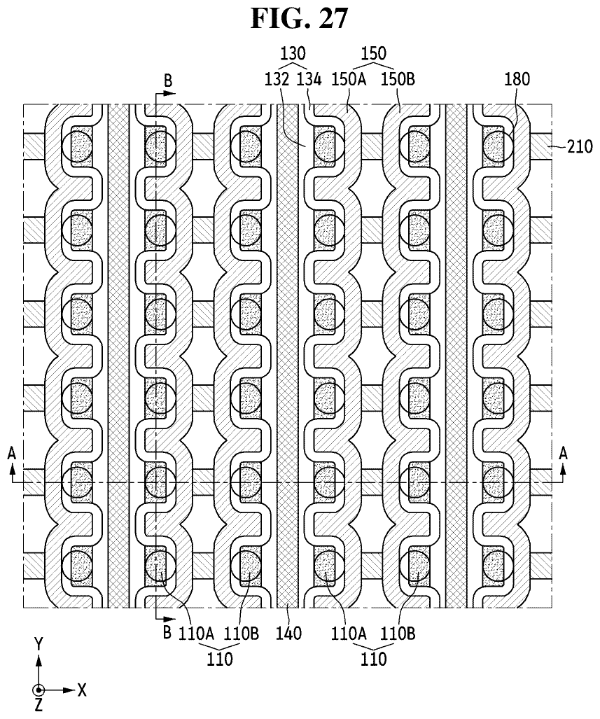

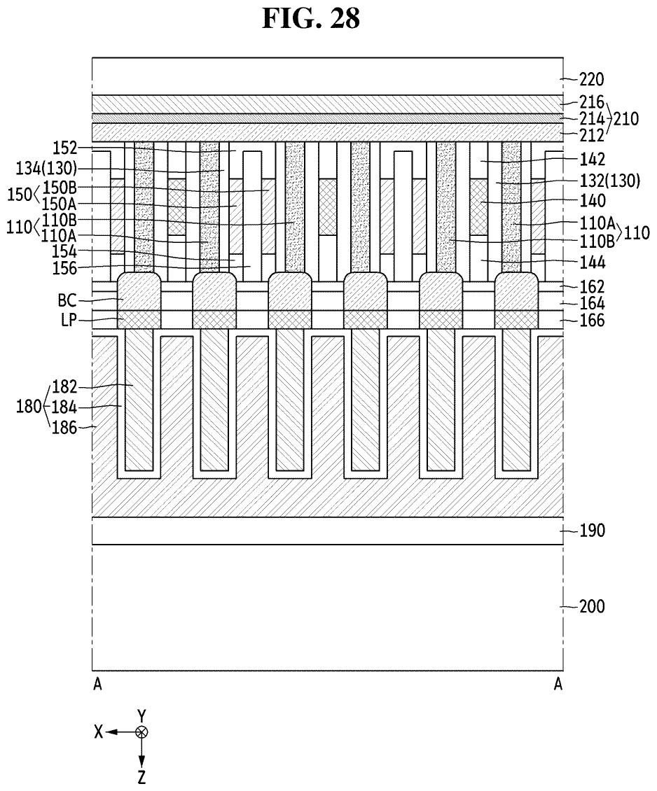

Referring to FIGS. 27 and 28, the conductive line 210 and the capping film 220 are formed.

For example, the conductive line 210 and the capping film 220 may be sequentially stacked on the plurality of active patterns 110, the insulating pattern 130, the first lower spacer 152, and the second lower spacer 142. The conductive line 210 and the capping film 220 may each extend long in the first direction X. The conductive line 210 may be commonly connected to one row of active patterns 110 arranged along the first direction X.

In some example embodiments, the conductive line 210 may include the first conductive film 212, the second conductive film 214, and the third conductive film 216 that are sequentially stacked.

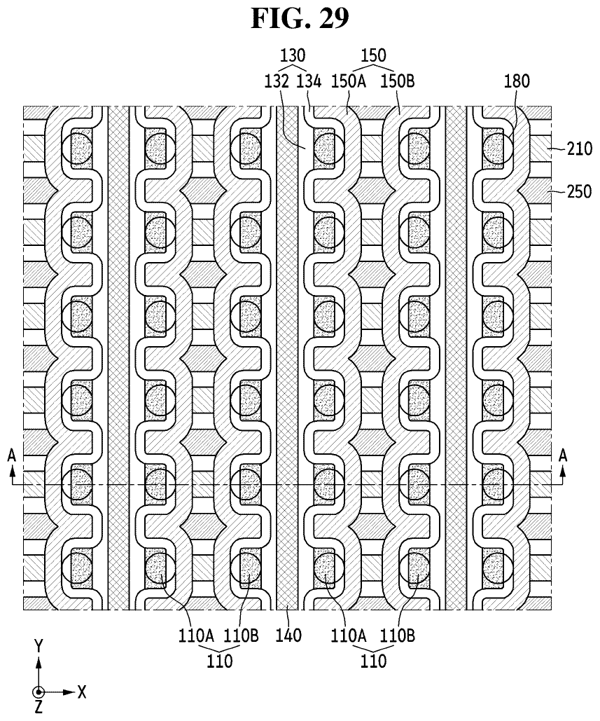

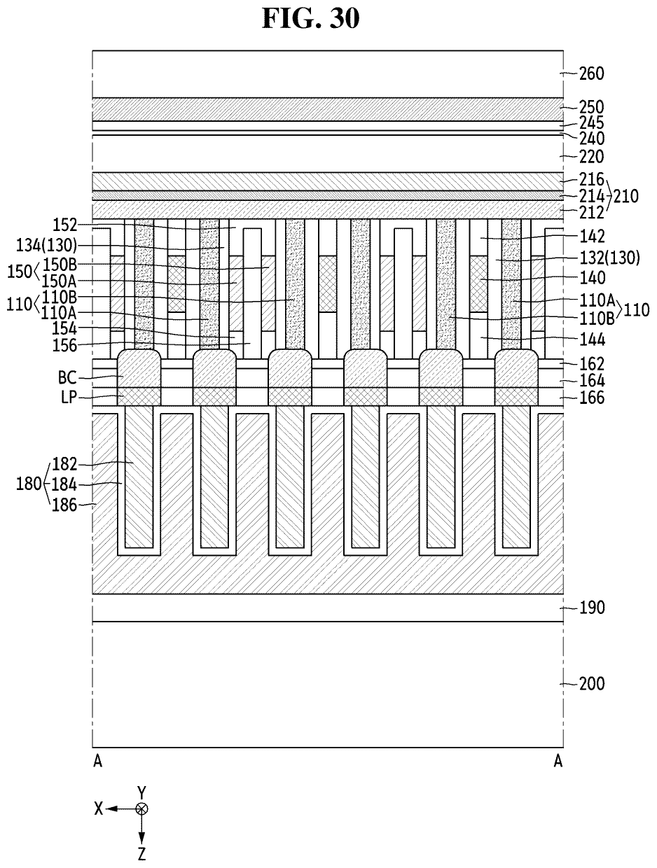

Referring to FIGS. 29 and 30, the liner film 240, the spacer film 245, and the shield conductive film 250 are formed.

The liner film 240 may be stacked on the conductive line 210 and the capping film 220. For example, the liner film 240 may conformally extend along the profiles of the side surface and upper surface of the capping film 220, the side surfaces of the conductive line 210, the upper surface of the insulating pattern 130, the upper surface of the first lower spacer 152, and the upper surface of the second lower spacer 142.

The spacer film 245 may be stacked on the liner film 240. For example, the spacer film 245 may conformally extend along the profiles of the side surface and upper surface of the liner film 240.

The shield conductive film 250 may be stacked on the spacer film 245. At least a part of the shield conductive film 250 may be interposed between the conductive lines 210 arranged along the second direction Y. For example, the shield conductive film 250 may be formed to fill at least a part of the region between one conductive line 210 and the other conductive line 210. After forming the shield conductive film 250, the lower insulating film 260 that covers at least a part of the shield conductive film 250 may be formed.

Next, referring to FIGS. 1 to 4, the carrier substrate 200 is removed. As a result, the semiconductor memory device described above using FIGS. 1 to 4 may be fabricated.

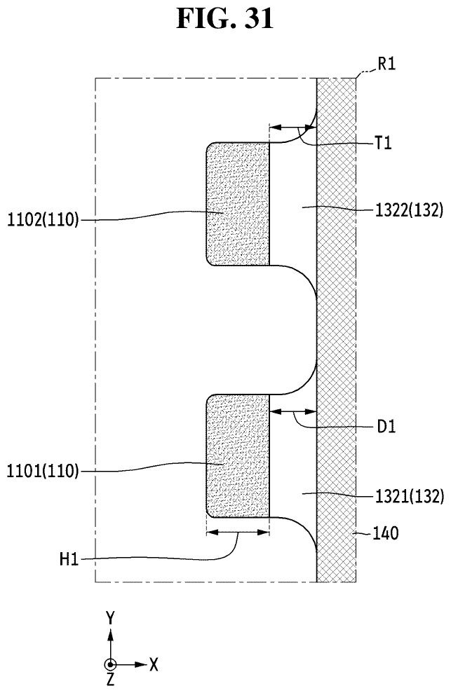

FIG. 31 is an intermediate step diagram for explaining a method for fabricating a semiconductor memory device according to some example embodiments. For convenience of explanation, repeated parts of contents explained above using FIGS. 1 to 30 will be briefly explained or omitted. For reference, FIG. 31 is an intermediate step diagram for explaining steps after FIGS. 14 and 15.

Referring to FIG. 31, in the method for fabricating the semiconductor memory device according to some example embodiments, the recess 132R exposes the back gate electrode 140. Since the formation of the recess 132R is similar to that described above using FIGS. 16 and 17, the detailed description thereof will not be provided below.

Next, the steps described above using FIGS. 18 to 30 may be performed. In this way, the semiconductor memory device described above using FIGS. 1 and 5A may be fabricated.

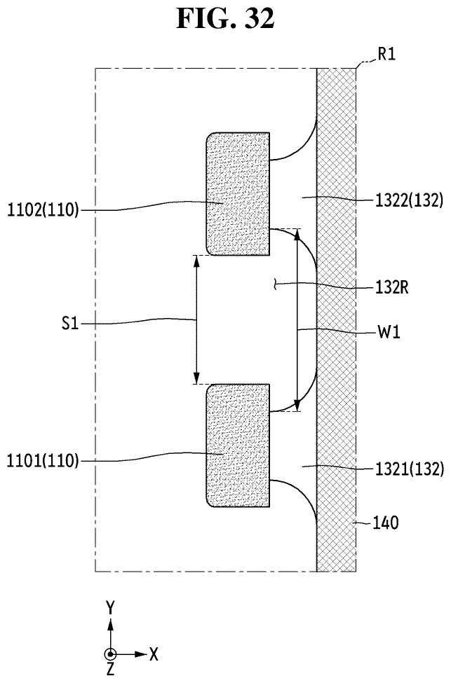

FIG. 32 is an intermediate step diagram for explaining the method for fabricating the semiconductor memory device according to some example embodiments. For convenience of explanation, repeated parts of contents explained above using FIGS. 1 to 30 will be briefly explained or omitted. For reference, FIG. 32 is an intermediate step diagram for explaining steps after FIGS. 14 and 15.

Referring to FIG. 32, in the method for fabricating the semiconductor memory device according to some example embodiments, the recess 132R exposes a part of the first side surface 110S1. For example, in the recess process described above using FIGS. 16 and 17, a part of the first insulating film 132 may be further recessed in the second direction Y.

Next, the steps described above using FIGS. 18 to 30 may be performed. As a result, the semiconductor memory device described above using FIGS. 1 and 5B may be fabricated.

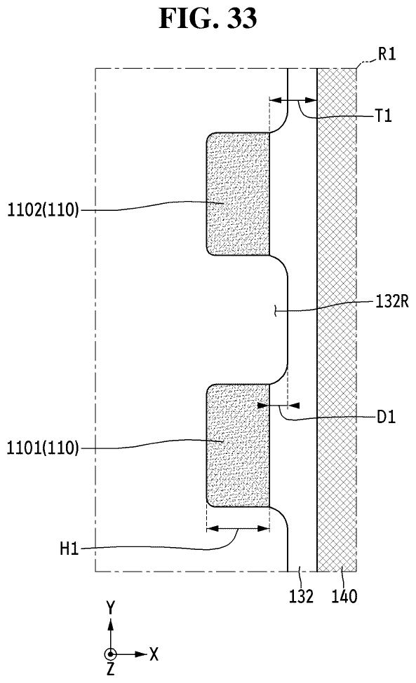

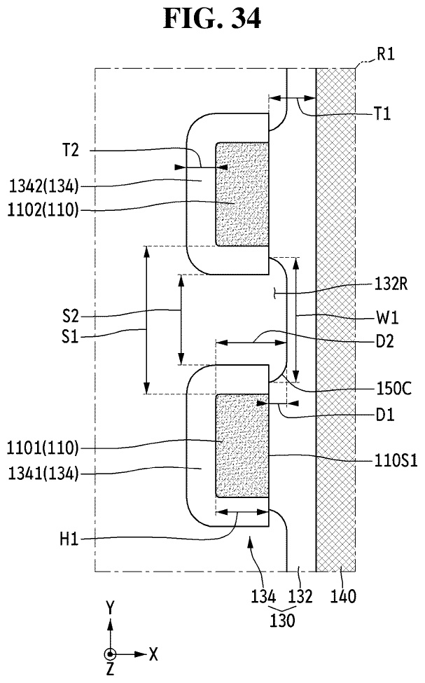

FIGS. 33 and 34 are intermediate step diagrams for describing the method for fabricating a semiconductor memory device according to some example embodiments. For convenience of description, repeated parts of contents explained above using FIGS. 1 to 30 will be briefly described or omitted. For reference, FIG. 33 is an intermediate step diagram for describing steps after FIGS. 14 and 15.

Referring to FIG. 33, a recess 132R is formed inside the first insulating film 132. Since the formation of the recess 132R is similar to that described above using FIGS. 16 and 17, detailed description thereof will not be provided below.

Referring to FIG. 34, a second insulating film 134 is formed.

The second insulating film 134 may include a third sub-insulating film 1341 and a fourth sub-insulating film 1342 that are separated from each other in the second direction Y. The third sub-insulating film 1341 may surround the side surfaces of the first active pattern 1101 along which the first insulating film 132 does not extend, and the fourth sub-insulating film 1342 may surround the side surfaces of the second active pattern 1102 along which the first insulating film 132 does not extend.

In some example embodiments, the second insulating film 134 may be formed by an oxidation process. The oxidation process may include, but is not limited to, an ISSG (In-Situ Steam Generation) process. In such a case, the second insulating film 134 may be formed by oxidizing a part of each active pattern 110.

In some example embodiments, the width W1 of the recess 132R in the second direction Y may be greater than the distance S2 by which the third sub-insulating film 1341 and the fourth sub-insulating film 1342 are spaced apart in the second direction Y.

In some example embodiments, the width W1 of the recess 132R in the second direction Y may be smaller than the distance S1 by which the first active pattern 1101 and the second active pattern 1102 are spaced apart in the second direction Y.

In concluding the detailed description, those skilled in the art will appreciate that many variations and modifications may be made to the example embodiments described herein without substantially departing from the principles of the present disclosure. Therefore, the disclosed example embodiments of the disclosure are used in a generic and descriptive sense only and not for purposes of limitation.

What is claimed is:

1. A semiconductor memory device comprising:
an active pattern including a first side surface and a second side surface opposite to each other in a first direction;
a conductive line extending on a bottom surface of the active pattern in the first direction;
a first insulating film extending on the first side surface of the active pattern in a second direction, the second direction intersecting the first direction;
a gate electrode extending on the second side surface of the active pattern in the second direction; and
a data storage structure on an upper surface of the active pattern,
wherein the gate electrode includes
a first gate portion spaced apart from the active pattern in the first direction, and
a second gate portion spaced apart from the active pattern in the second direction,
the second gate portion includes a convex surface that is convex toward the first insulating film, and
a maximum length of the second gate portion in the first direction is a distance from the second side surface of the active pattern to a furthest distance the second gate portion extends in the first direction, and
the maximum length of the second gate portion is greater than or equal to a width of the active pattern in the first direction.

2. The semiconductor memory device of claim 1, wherein the maximum length of the second gate portion is greater than the width of the active pattern in the first direction.

3. The semiconductor memory device of claim 1, further comprising:
a second insulating film between the active pattern and the gate electrode and between the first insulating film and the gate electrode.

4. The semiconductor memory device of claim 1, wherein
the second gate portion includes
a first portion extending from the first gate portion in the first direction, and
a second portion protruding from the first portion toward the active pattern and overlapping the first insulating film in the second direction.

5. The semiconductor memory device of claim 1, further comprising:
a back gate electrode extending in the second direction, on the first side surface of the active pattern,
wherein the first insulating film is between the active pattern and the back gate electrode.

6. The semiconductor memory device of claim 1, wherein the first insulating film includes a silicon oxide film.

7. The semiconductor memory device of claim 1, wherein the data storage structure includes a capacitor connected to the active pattern.

8. A semiconductor memory device comprising:
a first active pattern including a first side surface and a second side surface opposite to each other in a first direction;
a second active pattern spaced apart from the first active pattern in a second direction, the second direction intersecting the first direction;
a conductive line extending on a bottom surface of the first active pattern in the first direction;
a first insulating film extending on the first side surface of the first active pattern in the second direction;
a gate electrode extending on the second side surface in the second direction;
a second insulating film between the first active pattern and the gate electrode, and between the second active pattern and the gate electrode; and
a data storage structure on an upper surface of the first active pattern,
wherein the first insulating film includes a recess, recessed in the first direction, between the first active pattern and the second active pattern, and
a part of the gate electrode extends toward the recess.

9. The semiconductor memory device of claim 8, wherein the gate electrode includes a convex surface that is convex toward the recess.

10. The semiconductor memory device of claim 8, wherein a part of the second insulating film is between the first insulating film and the gate electrode.

11. The semiconductor memory device of claim 8, wherein a width of the recess in the second direction is greater than a distance the first active pattern and the second active pattern are spaced apart in the second direction.

12. The semiconductor memory device of claim 8, wherein
the second insulating film includes a first dielectric film between the first active pattern and the gate electrode, and a second dielectric film between the second active pattern and the gate electrode, and
a width of the recess in the second direction is greater than a distance the first dielectric film and the second dielectric film are spaced apart in the second direction.

13. The semiconductor memory device of claim 12, wherein the width of the recess in the second direction is smaller than a distance the first active pattern and the second active pattern are spaced apart in the second direction.

14. The semiconductor memory device of claim 12, wherein a part of the gate electrode comes into contact with the recess.

15. A semiconductor memory device comprising:
a first active pattern including a first side surface and a second side surface opposite to each other in a first direction;
a second active pattern spaced apart from the first active pattern in a second direction, the second direction intersecting the first direction;
a conductive line connected to the first active pattern and extending on a bottom surface of the first active pattern in the first direction;
a first insulating film on the first side surface of the first active pattern extending in the second direction;
a second insulating film extending along surfaces of the first active pattern, the second active pattern, and the first insulating film;
a gate electrode on the second insulating film extending in the second direction; and
a data storage structure connected to the first active pattern and on an upper surface of the first active pattern,
wherein the first insulating film includes a recess, recessed in the first direction, between the first active pattern and the second active pattern,
the gate electrode includes
a first gate portion on the first side surface of the first active pattern, and
a second gate portion between the first active pattern and the second active pattern, and
the second gate portion of the gate electrode includes a convex surface that is convex toward the recess.

16. The semiconductor memory device of claim 15, wherein a part of the second gate portion overlaps the first insulating film in the second direction.

17. The semiconductor memory device of claim 16, wherein the convex surface of the second gate portion overlaps the first insulating film in the first direction.

18. The semiconductor memory device of claim 15, wherein the second gate portion includes
a first portion extending from the first gate portion in the first direction, and
a second portion protruding from the first portion in the second direction, and the second portion overlapping the first insulating film in the second direction.

19. The semiconductor memory device of claim 15, further comprising:
a back gate electrode on the first side surface of the first active pattern extending in the second direction,
wherein the first insulating film is between the first active pattern and the back gate electrode, and between the second active pattern and the back gate electrode.

20. The semiconductor memory device of claim 15, wherein the data storage structure includes a lower electrode, a capacitor dielectric film, and an upper electrode sequentially stacked on the upper surface of the first active pattern.
